(19) United States
(12) Patent Application Publication
(10) Pub. No.: US 2026/0032861 A1
(43) Pub. Date: Jan. 29, 2026

(54) COOLANT FILTER STRUCTURE AND LIQUID COOLING SYSTEM USING SAME

(71) Applicant: DELTA ELECTRONICS, INC., Taoyuan City (TW)

(72) Inventors: Li-An Chung, Taoyuan City (TW); Cih-Ping Wang, Taoyuan City (TW); Sheng-Chi Wu, Taoyuan City (TW); Yu-Cheng Chang, Taoyuan City (TW); Chung-Ju Tsai, Taoyuan City (TW)

(21) Appl. No.: 19/273,941

(22) Filed: Jul. 18, 2025

Related U.S. Application Data
(60) Provisional application No. 63/676,560, filed on Jul. 29, 2024.

(30) Foreign Application Priority Data
Dec. 20, 2024 (CN) 202423156019.3

(51) Int. Cl. H05K 7/20

(52) U.S. Cl. CPC H05K 7/20272; H05K 7/20763; H05K 7/20254

(57) ABSTRACT

A coolant filter structure for a liquid cooling system is disclosed, and includes a container body, an upper cover, a fluid inlet, a fluid outlet and a filter element. The container body is used for containing a cooling liquid and includes an upper opening. The upper cover is detachably disposed above the container body for sealing the upper opening. The fluid inlet is arranged below the container body. The cooling liquid is allowed flowing into the container body from a bottom of the container body through the fluid inlet. The fluid outlet is arranged on a lateral side of the container body. The filter element vertically penetrates the container body. the fluid inlet is in communication with the upper opening and the fluid outlet through the filter element. The cooling liquid in the container body is allowed to flow through the filter element and be discharged from the fluid outlet.

### CROSS-REFERENCE TO RELATED APPLICATION

This application claims the benefit of U.S. Provisional Application No. 63/676,560 filed on Jul. 29, 2024, and entitled “AIR ASSISTED LIQUID COOLING SYSTEM WITH TOOLLESS SANITARY TRI-CLAMP DESIGN, Y-SHAPED TUBE DESIGN AND FAN BLIND INSERTION DESIGN”. This application claims priority to China Patent Application No. 202423156019.3, filed on Dec. 20, 2024. The entireties of the above-mentioned patent applications are incorporated herein by reference for all purposes.

### FIELD OF THE INVENTION

The present disclosure relates to a filter structure, and more particularly to a coolant filter structure and a liquid cooling system using the same, capable of preventing the coolant from overflowing and leaking during repairing and replacing the filter element through the pipeline design.

### BACKGROUND OF THE INVENTION

At present, as the CPU and GPU in the server generate more and more heat, the liquid cooling system is gradually used instead of the air cooling system. The liquid cooling system is usually used with a cold plate in the server for heat dissipation. The cold plate includes a micro-channel structure for heat exchange. The micro-channel size is usually <100 μm. Therefore, the liquid cooling equipment will be equipped with filter element to prevent the cold plate from being blocked by impurities (particles) in the supplied coolant.

Generally speaking, it is necessary to drain the coolant of the cooling system before replacing and repairing the filter element to avoid a large amount of coolant overflowing during replacement. Furthermore, when replacing the filter element, even if there is no need to drain the fluid, the liquid level inside the filter element will still be full of liquid during replacement, and it is easy for the coolant to overflow due to shaking. In addition, when the filter element is in use, it is easy to have the air inside, so as to cause the air blockage in the filter element.

Therefore, there is a need of providing a coolant filter structure and a liquid cooling system using the same capable of preventing the coolant from overflowing and leaking during repairing and replacing the filter element through the pipeline design, so as to obviate the drawbacks encountered by the prior arts.

### SUMMARY OF THE INVENTION

An object of the present disclosure is to provide a coolant filter structure and a liquid cooling system using the same capable of preventing the coolant from overflowing and leaking during repairing and replacing the filter element through the pipeline design.

Another object of the present disclosure is to provide a coolant filter structure and a liquid cooling system using the same. Through the structural design, the liquid level in the coolant filter structure is maintained to be lower than the height of the upper opening, and it helps to avoid leakage during replacement or avoid leakage caused by full liquid when replacing the internal filter element. For the liquid filling stage after replacement, the internal space of the container body can be effectively filled with the coolant. Furthermore, since the container body is connected to the pipeline of the liquid cooling system, there is no need to remove the container body when replacing or repairing the filter element, so it is not easy to cause overflow or leakage of the coolant. On the other hand, the detachable upper cover above the container body allows the installation of an exhaust valve, and it facilitates the coolant fluid flowing into the container body from the bottom can to discharge the accumulated air inside the container body. Thereby, it allows the inside of the container body to be easily filled with the coolant, and it also helps to avoid the air blockage problem caused by the filter element not being full of liquid. The upper cover further includes a cap bump protruding downwardly and corresponding to the upper opening of the container body. When the upper opening is sealed by the upper cover, the cap bump is extended downwardly into the accommodation space to expel the coolant in the accommodation space. When the upper cover is detached to open the upper opening for replacing or maintaining the filter element, the volume of the cap bump moved out of the accommodation space is compensated by the liquid, and it causes the coolant in the accommodation space to further reduce the liquid level, so that the liquid level is effectively lowered to prevent the coolant from overflowing and leakage. Certainly, the shape and the size of the cap bump are adjustable according to the practical requirements. In some practical applications, the upper cover and the filter element are directly connected to form an integrated structure. It allows the filter element to provide the same performance as the cap bump protruding downwardly. When the filer element below the upper cover is removed out of the accommodation, the liquid level is lowered, so as to achieve the purpose of preventing the coolant from overflowing and leakage. The flow channel of the coolant filter structure adopts a pipeline design that enters from the bottom and exits from the lateral side, and the coolant filter structure can be connected to the coolant transmission pipelines of the liquid cooling system, but not limited to the location of the connection. The fluid inlet arranged under the container body can be guided to the system main pump suction or the system reservoir by using any form of the mini pump with a buffer tank. When the filter element needs to be replaced or repaired, the system main pump or the mini pump can be actuated to reduce the coolant level and the liquid pressure inside the coolant filter structure effectively. The liquid pressure range can be for example but not limited to positive pressure or vacuum, and the leakage of the coolant is avoided when the upper cover of the coolant filter structure is opened. The present disclosure includes the industrial applicability and the inventive steps.

In accordance with an aspect of the present disclosure, a coolant filter structure is provided and includes a container body, an upper cover, a fluid inlet, a fluid outlet and a filter element. The container body is configured to contain a coolant, wherein the container body includes an upper opening. The upper cover is detachably disposed above the container body and configured to seal the upper opening. The fluid inlet is arranged below the container body, wherein the coolant is allowed flowing into the container body from a bottom of the container body through the fluid inlet. The fluid outlet is arranged on a lateral side of the container body. The filter element vertically penetrates the container body. The fluid inlet is in communication with the upper opening and the fluid outlet through the filter element, and the coolant in the container body is allowed to flow through the filter element and be discharged from the fluid outlet.

In an embodiment, the upper cover includes a cap bump spatially corresponding to the upper opening and accommodated in the container body when the upper cover seals the upper opening.

In an embodiment, the upper cover includes a through hole, and the coolant filter structure further includes an exhaust valve disposed on the upper cover, in communication with an accommodation space of the container body through the through hole, and configured to eliminate a gas in the container body.

In an embodiment, when the upper cover is detached from the upper opening, the coolant forms a liquid level in the container body that is lower than the upper opening, and the filter element is allowed to pass through the upper opening.

In an embodiment, the filter element is directly connected to the upper cover to form an integrated structure.

In an embodiment, the coolant filter structure further includes a gasket, wherein the gasket is detachably disposed between the container body and the upper cover, and the container body and the upper cover are connected through a sanitary clamp, so that the gasket is sandwiched between the container body and the upper cover.

In accordance with another aspect of the present disclosure, a liquid cooling system is provided and includes a reservoir and pumping unit, a plurality of coolant transmission pipelines and a plurality of coolant filter structures. The reservoir and pumping unit includes a system reservoir and is configured to store a coolant temporarily. The plurality of coolant transmission pipelines is configured to guide the coolant from the system reservoir to a plurality of heat dissipation modules for heat exchange and then guide the coolant back to the system reservoir. The plurality of coolant filter structures are disposed in the plurality of coolant transmission pipelines, respectively, and configured to purify the coolant before the coolant flows to the plurality of heat dissipation modules. Each of the plurality of coolant filter structures includes a container body, an upper cover, a fluid inlet, a fluid outlet and a filter element. The container body is configured to contain a coolant, wherein the container body includes an accommodation space and an upper opening. The accommodation space is configured to accommodate the coolant and in communication with an exterior through the upper opening. The upper cover is detachably disposed above the container body and configured to seal the upper opening. The fluid inlet is arranged below the container body and in communication with the accommodation space, wherein the coolant is allowed flowing into the accommodation space from a bottom of the container body through the fluid inlet. The fluid outlet is arranged on a lateral side of the container body. The filter element is accommodated within the accommodation space through the upper opening and arranged between the fluid inlet and the fluid outlet, wherein the coolant enters the accommodation space through the fluid inlet, flows through the filter element, and then is discharged through the fluid outlet.

In an embodiment, the liquid cooling system further includes a buffer tank, wherein the fluid inlets of the plurality of cooling filter structures are jointly coupled to the buffer tank, and the buffer tank is configured to collect the coolant contained in the accommodation spaces of the plurality of cooling filter structures through the fluid inlets when the plurality of coolant transmission pipelines stop transporting the coolant.

In an embodiment, the liquid cooling system further includes a mini pump connected to the buffer tank, wherein the mini pump is configured to transport the coolant from the buffer tank to a main pump suction of the reservoir and pumping unit or the system reservoir.

In an embodiment, the upper cover includes a cap bump spatially corresponding to the upper opening and accommodated in the container body when the upper cover seals the upper opening.

In an embodiment, the upper cover includes a through hole, and the coolant filter structure further includes an exhaust valve disposed on the upper cover, in communication with the accommodation space of the container body through the through hole, and configured to eliminate a gas in the container body.

In an embodiment, when the upper cover is detached from the upper opening, the coolant forms a liquid level in the container body that is lower than the upper opening, and the filter element is allowed to pass through the upper opening.

In an embodiment, the filter element is directly connected to the upper cover to form an integrated structure.

In an embodiment, each of the plurality of coolant filter structures further includes a gasket, wherein the gasket is detachably disposed between the container body and the upper cover, and the container body and the upper cover are connected through a sanitary clamp, so that the gasket is sandwiched between the container body and the upper cover.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a schematic structural view illustrating a liquid cooling system according to a first embodiment of the present disclosure;

FIG. 2 is a schematic structural view illustrating the coolant filter structure with the upper cover sealed according to the first embodiment of the present disclosure;

FIG. 3 is a schematic structural view illustrating the coolant filter structure with the upper cover opened according to the first embodiment of the present disclosure;

FIG. 4 is a schematic structural view illustrating a liquid cooling system according to a second embodiment of the present disclosure;

FIG. 5 is a structural perspective view illustrating the coolant filter structure according to the second embodiment of the present disclosure;

FIG. 6 is an exploded view illustrating the coolant filter structure according to the second embodiment of the present disclosure;

FIG. 7 is a cross-section view illustrating the coolant filter structure with the upper cover sealed according to the second embodiment of the present disclosure;

FIG. 8 is a cross-section view illustrating the coolant filter structure with the upper cover opened according to the second embodiment of the present disclosure;

FIG. 9 is a schematic diagram showing the pipeline connections between multiple coolant filter structures and other components according to the second embodiment of the present disclosure; and

FIG. 10 is a schematic diagram showing the pipeline connection of the buffer tank and the mini pump of the liquid cooling system according to the second embodiment of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “upper,” “lower,” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items.

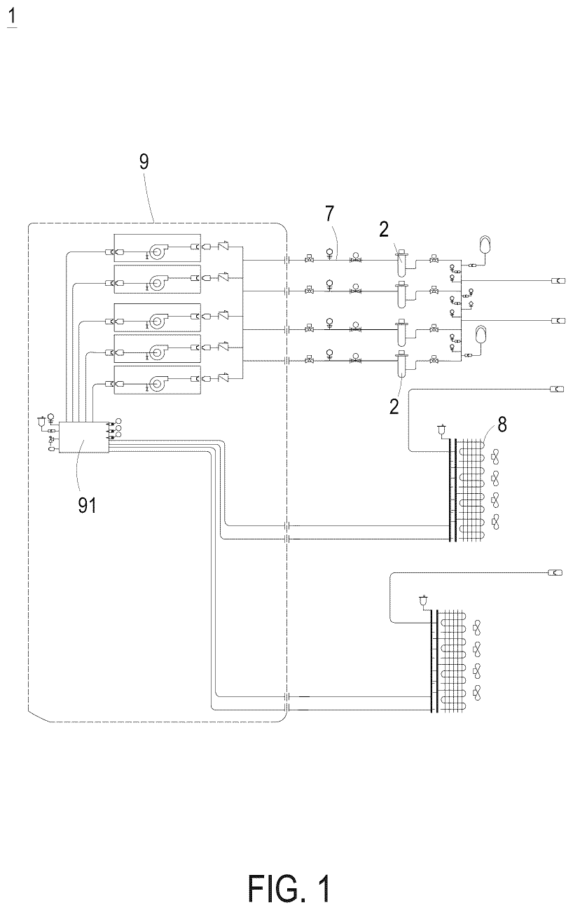

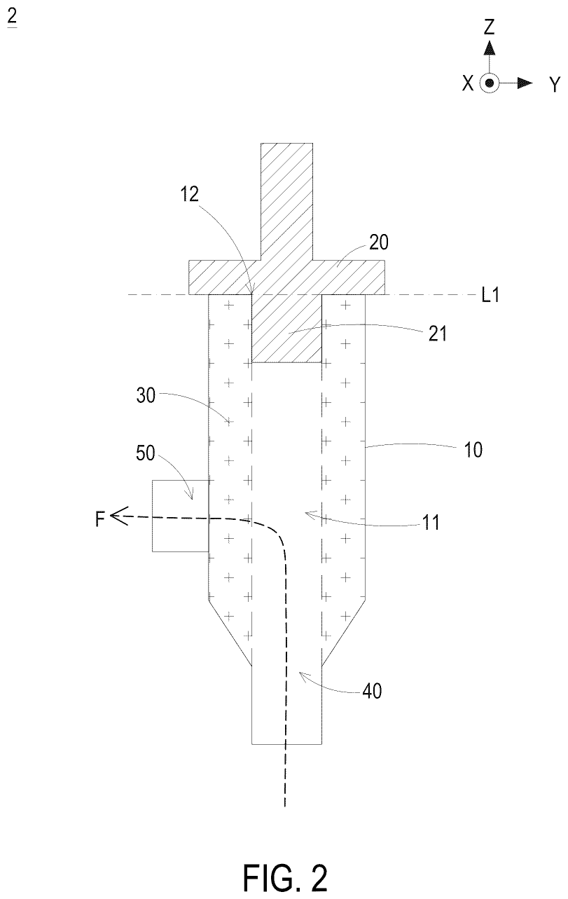

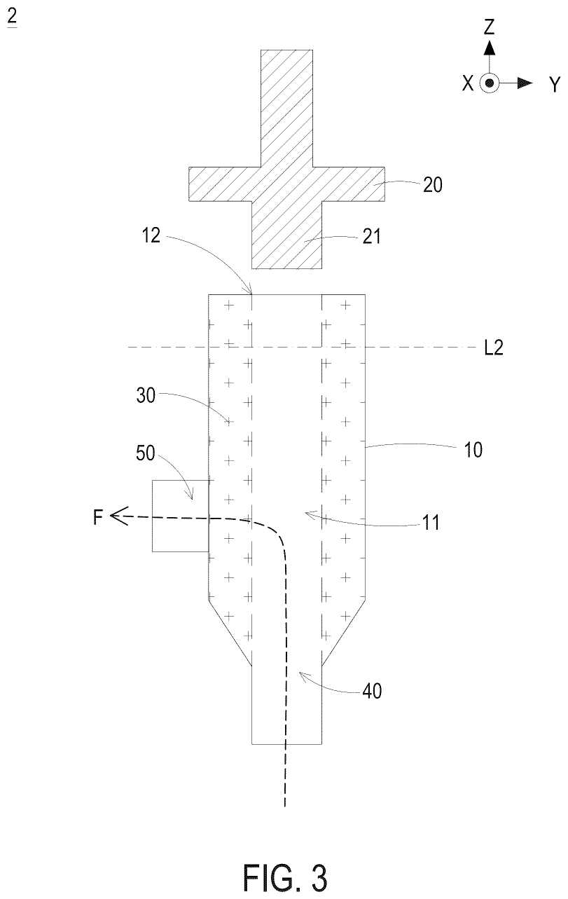

FIG. 1 is a schematic structural view illustrating a liquid cooling system according to a first embodiment of the present disclosure. FIG. 2 is a schematic structural view illustrating the coolant filter structure with the upper cover sealed according to the first embodiment of the present disclosure. FIG. 3 is a schematic structural view illustrating the coolant filter structure with the upper cover opened according to the first embodiment of the present disclosure. In the embodiment, the present disclosure provides a coolant filter structure 2 for purifying the coolant and a liquid cooling system 1 using the same. The liquid cooling system 1 includes a reservoir and pumping unit (RPU) 9, at least one coolant transmission pipeline 7 and at least one coolant filter structure 2. The reservoir and pumping unit 9 includes a system reservoir 91 and is configured to store a coolant temporarily. The coolant transmission pipeline 7 is not limited to the transmission method and the transmission path. Preferably but not exclusively, the coolant is transported from the system reservoir 91 to a heat dissipation module 8 for heat exchange, and then the coolant is transported back to the system reservoir 91. In the embodiment, the heat dissipation module 8 is, for example, a cold plate in the server, and includes micro-channel structure with the size smaller than 100 μm, so that the heat exchange is performed through the flow of coolant to provide effective heat dissipation for the server. Notably, the coolant filter structure 2 is in communication with the coolant transmission pipeline 7 and configured to purify the coolant before the coolant flows to the heat dissipation module 8. In that, the impurities above 25 μm are filtered out. It prevents the coolant supplied from the coolant transmission pipeline 7 to the heat dissipation module 8 from containing excessive impurities and causing blockage.

Furthermore, in the embodiment, the coolant filter structure 2 further improves the convenience of use through pipeline design, and avoids leakage or overflow problems during maintenance. In the embodiment, the coolant filter structure 2 includes a container body 10, an upper cover 20, a fluid inlet 40, a fluid outlet 50 and a filter element 30. The container body 10 includes an accommodation space 11 for containing a coolant. In the embodiment, the container body 10 further includes an upper opening 12. The accommodation space is 11 in communication with an exterior through the upper opening 12. The upper cover 20 is detachably disposed above the container body 10 by buckling, screwing or clamping, and configured to seal the upper opening 12. The fluid inlet 40 is arranged below the container body 10 and in communication with the accommodation space 11. In the embodiment, the coolant is allowed flowing into the accommodation space 11 of the container body 10 from a bottom of the container body 10 through the fluid inlet 40. The fluid outlet 50 is arranged on a lateral side of the container body 10. The filter element 30 vertically penetrates the container body 10. That is, the filter element 30 is accommodated within the accommodation space 11 through the upper opening 12, and arranged between the fluid inlet 40 and the fluid outlet 50. Preferably but not exclusively, in the embodiment, the fluid inlet 40 is upwardly in communication with the upper opening 12 through the filter element 30 or the accommodation space 11. Moreover, the fluid inlet 40 is laterally in communication with the fluid outlet 50 through the filter element 30 or the accommodation space 11. In the embodiment, the coolant in the container body 10 is allowed to flow through the filter element 30 and be discharged from the fluid outlet 50.

When the liquid cooling system 1 is in operation, the coolant transmission pipe 7 introduces the coolant into the container body 10 through the fluid inlet 40 at the bottom. Moreover, after filtering by the filter element 30, the coolant is discharged out of the container body 10 through the fluid outlet 50 at the lateral wall, so that the purified coolant can be supplied to the heat dissipation module 8. The flow direction F of the coolant in the coolant filter structure 2 of the present disclosure is as shown in the figure. Notably, the flow channel of the coolant filter structure 2 adopts a pipeline design that enters from below and is led out from the lateral side. The coolant filter structure 2 can be connected to the coolant transmission pipeline 7 of the liquid cooling system 1 arbitrarily, and is not limited to the connected position. On the other hand, when the filter element 30 of the coolant filter structure 2 is replaced or repaired, since the upper opening 12 of the container body 10 is designed upward, the liquid level L1 in the coolant filter structure 2 can be maintained not exceeding the height of the upper opening 12 after the upper cover 20 is opened. It helps to avoid leakage during replacement or avoid leakage caused by full liquid when replacing the internal filter element 30.

In the embodiment, the upper cover 20 further includes a cap bump 21. The cap bump 21 is spatially corresponding to the upper opening 12. Moreover, the cap bump 21 protrudes downwardly and is accommodated in the accommodation space 11 of the container body 10 when the upper cover 20 seals the upper opening 12. When the liquid cooling system 1 is in operation, the upper cover 20 is used to seal the upper opening 12, and the cap bump 21 is extended downwardly into the accommodation space 11 to expel the coolant in the accommodation space 11, and prevent the coolant in the accommodation space 11 from flowing out, so that the liquid level L1 of the coolant is maintained not exceeding the height of the upper opening 12, as shown in FIG. 2. When the upper cover 20 is opened to replace or repair the filter element 30, the volume of the cap bump 21 of the upper cover 20 moved out of the accommodation space 11 is compensated by the liquid, so that the coolant forms another liquid level L2 below the upper opening 12 of the container body 10. At this time, it allows replacing or maintain the filter element 30 through the upper opening 12. In other words, through the design of the cap bump 21, the liquid level of the coolant in the accommodation space 11 can be effectively lowered when the filter element 30 is repaired and replaced, thereby preventing the coolant from overflowing and leaking. Certainly, the shape and the size of the cap bump 21 are adjustable according to the practical requirements.

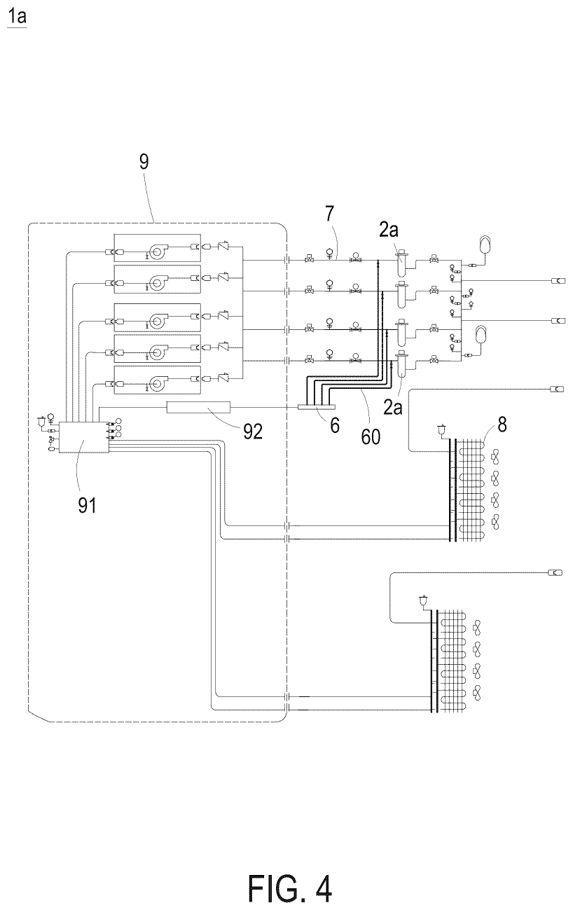

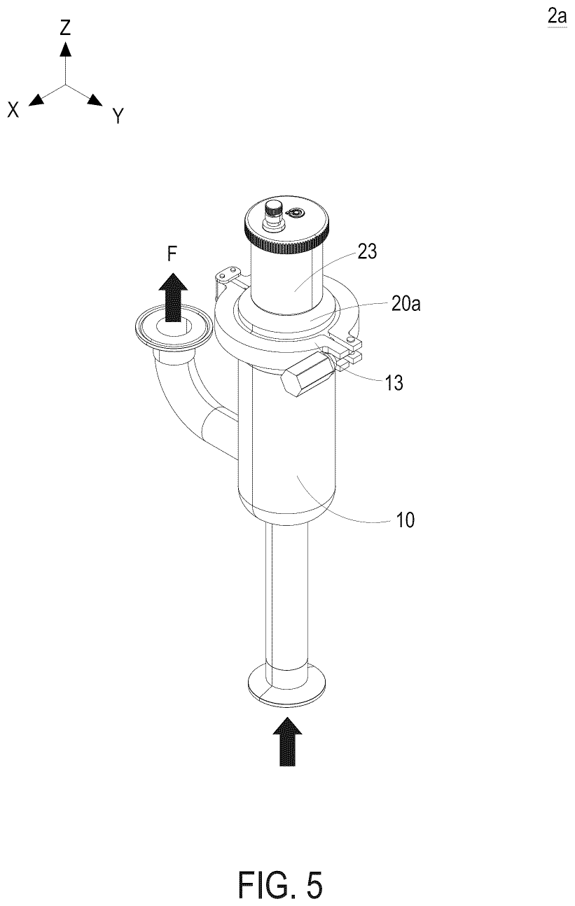

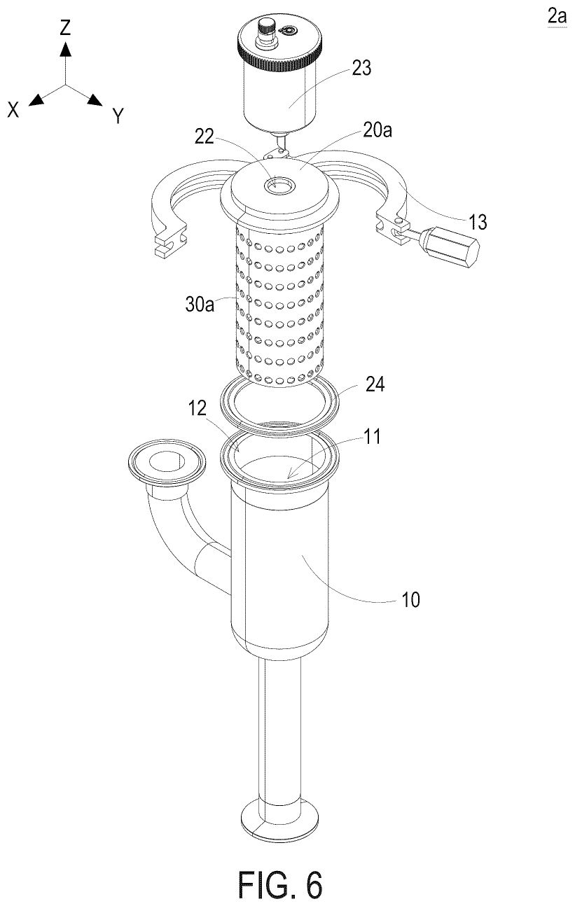

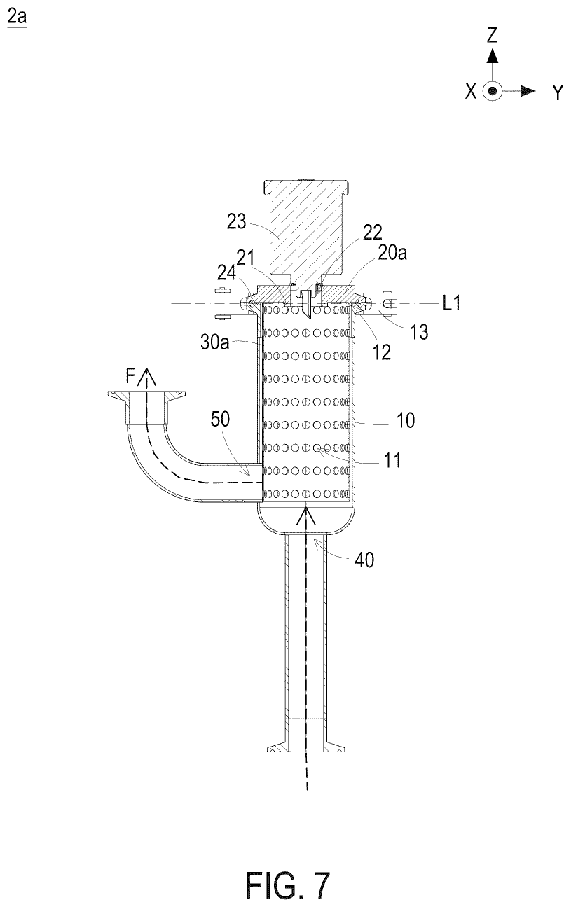

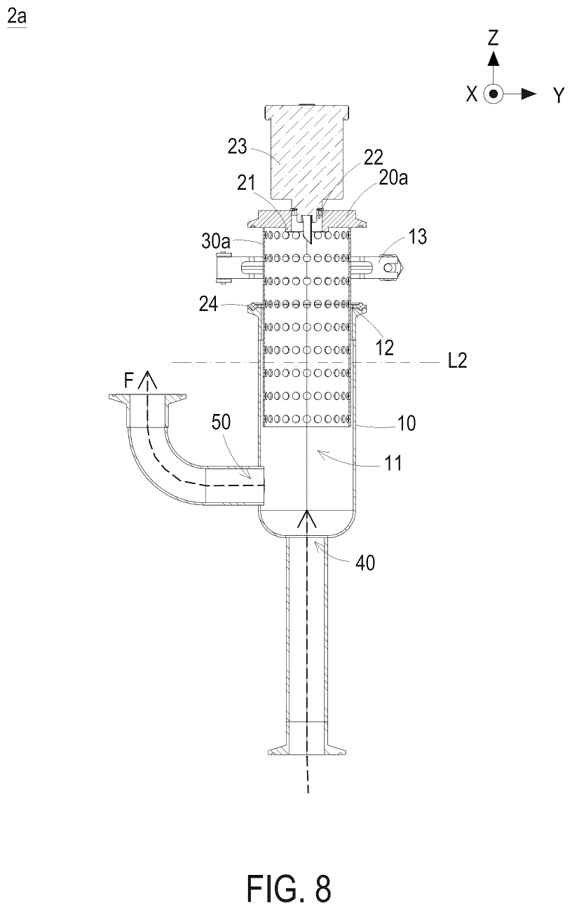

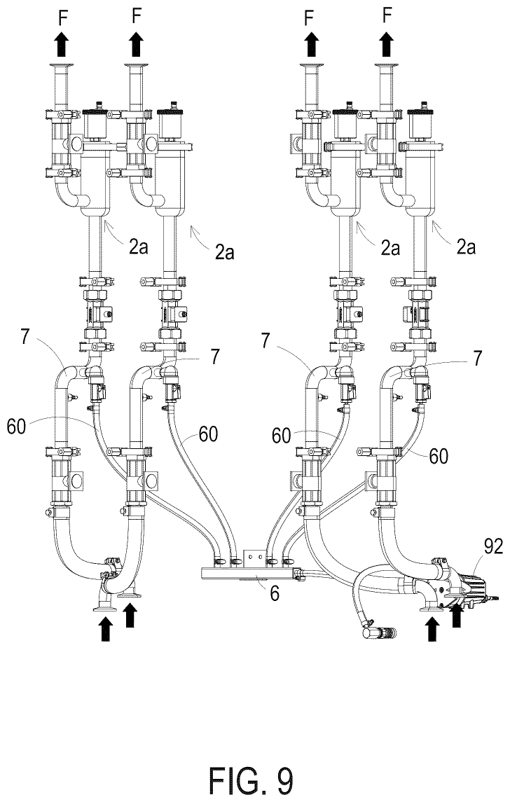

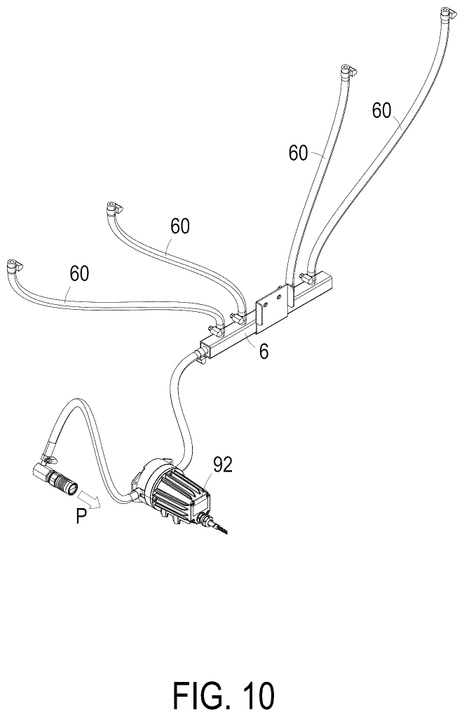

FIG. 4 is a schematic structural view illustrating a liquid cooling system according to a second embodiment of the present disclosure. FIG. 5 is a structural perspective view illustrating the coolant filter structure according to the second embodiment of the present disclosure. FIG. 6 is an exploded view illustrating the coolant filter structure according to the second embodiment of the present disclosure. FIG. 7 is a cross-section view illustrating the coolant filter structure with the upper cover sealed according to the second embodiment of the present disclosure. FIG. 8 is a cross-section view illustrating the coolant filter structure with the upper cover opened according to the second embodiment of the present disclosure. FIG. 9 is a schematic diagram showing the pipeline connections between multiple coolant filter structures and other components according to the second embodiment of the present disclosure. FIG. 10 is a schematic diagram showing the pipeline connection of the buffer tank and the mini pump of the liquid cooling system according to the second embodiment of the present disclosure. In the embodiment, the structures, elements and functions of the liquid cooling system 1a and the coolant filter structure 2a are similar to those of the liquid cooling system 1 and the coolant filter structure 2 of FIG. 1 to FIG. 3, and are not redundantly described herein. Please refer to FIG. 4 to FIG. 10. In the embodiment, the liquid cooling system 1a includes a reservoir and pumping unit (RPU) 9, a plurality of coolant transmission pipelines 7 and a plurality of coolant filter structures 2a. The plurality of coolant transmission pipelines 7 respectively transport the coolant to the corresponding plurality of heat dissipation modules 8 through the system reservoir 91 for heat exchange, and then transport the coolant back to the system reservoir 91. Preferably but not exclusively, the plurality of coolant filter structures 2a are respectively disposed and corresponding to the paths in front of where the plurality of cooling liquid transmission pipes 7 transport the coolant to the heat dissipation module 8 for purifying the coolant. In the embodiment, each of the plurality of coolant filter structures 2a includes a container body 10, an upper cover 20a, a fluid inlet 40, a fluid outlet 50 and a filter element 30a. Preferably but not exclusively, the filter element 30a is directly connected to the upper cover 20a to form an integrated structure. In the embodiment, the coolant filter structure 2a further includes a gasket 24. The gasket 24 is detachably disposed between the container body 10 and the upper cover 20a. In addition, the container body 10 and the upper cover 20a are connected through a sanitary clamp 13, so that the gasket 24 is sandwiched between the container body 10 and the upper cover 20a.

When the liquid cooling system 1a is in operation, the coolant transmission pipe 7 introduces the coolant into the corresponding container body 10 through the fluid inlet 40 at the bottom. Moreover, after filtering by the filter element 30a, the coolant is discharged out of the container body 10 through the fluid outlet 50 at the lateral wall, so that the purified coolant can be supplied to the corresponding heat dissipation module 8. In the embodiment, when the coolant flows through the coolant filter structure 2a along the flow direction F, which enters from the bottom and exits from the lateral side, the liquid level L1 of the coolant in the accommodation space 11 is maintained not exceeding the height of the upper opening 12. Since the cap bump 21 connected below the upper cover 20a and the filter element 30a are both accommodated in the accommodation space 11 when the upper opening 12 is sealed by the upper cover 20a, the filter element 30a can provide the same performance as the cap bump 21 protruding downwardly. When the filter element 30a is moved out of the accommodation space 11, the liquid level L2 of the coolant is reduced to prevent the coolant from overflowing and leaking. Certainly, the present disclosure is not limited thereto.

In the embodiment, the upper cover 20a includes a through hole 22, and the coolant filter structure 2a further includes an exhaust valve 23 disposed on the upper cover 20a, in communication with the accommodation space 11 of the container body 10 through the through hole 22, and configured to eliminate a gas in the container body 10. With the installation of the exhaust valve 23, when the coolant enters the accommodation space 11 through the fluid inlet 40 at the bottom of the container body 10, it allows the inflowing fluid of the coolant discharging the accumulated gas inside the accommodation space 11. Thereby, it allows the accommodation space 11 of the container body 10 being filled with the coolant easily, and it also helps to avoid the air blockage problem caused by the filter structure not being filled with liquid. Certainly, the present disclosure is not limited thereto.

On the other hand, in the embodiment, the liquid cooling system 1a further includes a buffer tank 6, wherein the fluid inlets 40 of the plurality of cooling filter structures 2a are jointly coupled to the buffer tank 6 through the tapping pipes 60, respectively. In this way, when the plurality of coolant transmission pipelines 7 stop transporting the coolant, the buffer tank 6 is capable of collecting the coolant contained in the accommodation spaces 11 of the plurality of cooling filter structures 2a through the fluid inlets 40. In the embodiment, the liquid cooling system 1a further includes a mini pump 92 connected to the buffer tank 6. Preferably but not exclusively, the mini pump 92 is configured to transport the coolant from the buffer tank 6 to a main pump suction P of the reservoir and pumping unit (RPU) 9 or the system reservoir 91. When the filter element 30a needs to be replaced or repaired, the system main pump or the mini pump 92 is actuated to reduce the liquid level L2 of the coolant and the liquid pressure inside the coolant filter structure 2a effectively. The liquid pressure range can be for example but not limited to positive pressure or vacuum, and the leakage of the coolant is avoided when the upper cover 20a of the coolant filter structure 2a is opened. Certainly, in other embodiments, any form of the mini pump 92 cooperated with the buffer tank 6 can be utilized to connect the fluid inlet 40 under the container body 10 for guiding the coolant to the system main pump suction port P or the system reservoir 91. The present disclosure is not limited thereto and not redundantly described hereafter.

In summary, the present disclosure provides a coolant filter structure and a liquid cooling system using the same capable of preventing the coolant from overflowing and leaking during repairing and replacing the filter element through the pipeline design. Through the structural design, the liquid level in the coolant filter structure is maintained to be lower than the height of the upper opening, and it helps to avoid leakage during replacement or avoid leakage caused by full liquid when replacing the internal filter element. For the liquid filling stage after replacement, the internal space of the container body can be effectively filled with the coolant. Furthermore, since the container body is connected to the pipeline of the liquid cooling system, there is no need to remove the container body when replacing or repairing the filter element, so it is not easy to cause overflow or leakage of the coolant. On the other hand, the detachable upper cover above the container body allows the installation of an exhaust valve, and it facilitates the coolant fluid flowing into the container body from the bottom can to discharge the accumulated air inside the container body. Thereby, it allows the inside of the container body to be easily filled with the coolant, and it also helps to avoid the air blockage caused by the filter element not being full of liquid. The upper cover further includes a cap bump protruding downwardly and corresponding to the upper opening of the container body. When the upper opening is sealed by the upper cover, the cap bump is extended downwardly into the accommodation space to expel the coolant in the accommodation space. When the upper cover is detached to open the upper opening for replacing or maintaining the filter element, the volume of the cap bump moved out of the accommodation space is compensated by the liquid, and it causes the coolant in the accommodation space to further reduce the liquid level, so that the liquid level is effectively lowered to prevent the coolant from overflowing and leakage. Certainly, the shape and the size of the cap bump are adjustable according to the practical requirements. In some practical applications, the upper cover and the filter element are directly connected to form an integrated structure. It allows the filter element to provide the same performance as the cap bump protruding downwardly. When the filer element below the upper cover is removed out of the accommodation, the liquid level is lowered, so as to achieve the purpose of preventing the coolant from overflowing and leakage. The flow channel of the coolant filter structure adopts a pipeline design that enters from the bottom and exits from the lateral side, and the coolant filter structure can be connected to the coolant transmission pipelines of the liquid cooling system, but not limited to the location of the connection. The fluid inlet arranged under the container body can be guided to the system main pump suction or the system reservoir by using any form of the mini pump with a buffer tank. When the filter element needs to be replaced or repaired, the system main pump or the mini pump can be actuated to reduce the coolant level and the liquid pressure inside the coolant filter structure effectively. The liquid pressure range can be for example but not limited to positive pressure or vacuum, and the leakage of the coolant is avoided when the upper cover of the coolant filter structure is opened. The present disclosure includes the industrial applicability and the inventive steps.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A coolant filter structure, comprising:
a container body, configured to contain a coolant, wherein the container body comprises an upper opening;
an upper cover, detachably disposed above the container body and configured to seal the upper opening;
a fluid inlet, arranged below the container body, wherein the coolant is allowed flowing into the container body from a bottom of the container body through the fluid inlet;
a fluid outlet, arranged on a lateral side of the container body; and
a filter element, vertically penetrating the container body, wherein the fluid inlet is in communication with the upper opening and the fluid outlet through the filter element, and the coolant in the container body is allowed to flow through the filter element and be discharged from the fluid outlet.

2. The coolant filter structure according to claim 1, wherein the upper cover comprises a cap bump spatially corresponding to the upper opening and accommodated in the container body when the upper cover seals the upper opening.

3. The coolant filter structure according to claim 1, wherein the upper cover comprises a through hole, and the coolant filter structure further comprises an exhaust valve disposed on the upper cover, in communication with an accommodation space of the container body through the through hole, and configured to eliminate a gas in the container body.

4. The coolant filter structure according to claim 1, wherein when the upper cover is detached from the upper opening, the coolant forms a liquid level in the container body that is lower than the upper opening, and the filter element is allowed to pass through the upper opening.

5. The coolant filter structure according to claim 1, wherein the filter element is directly connected to the upper cover to form an integrated structure.

6. The coolant filter structure according to claim 1, further comprising a gasket, wherein the gasket is detachably disposed between the container body and the upper cover, and the container body and the upper cover are connected through a sanitary clamp, so that the gasket is sandwiched between the container body and the upper cover.

7. A liquid cooling system, comprising:
a reservoir and pumping unit comprising a system reservoir and configured to store a coolant temporarily;
a plurality of coolant transmission pipelines configured to guide the coolant from the system reservoir to a plurality of heat dissipation modules for heat exchange and then guide the coolant back to the system reservoir; and
a plurality of coolant filter structures disposed in the plurality of coolant transmission pipelines, respectively, and configured to purify the coolant before the coolant flows to the plurality of heat dissipation modules, wherein each of the plurality of coolant filter structures comprises:
a container body, configured to contain a coolant, wherein the container body comprises an accommodation space and an upper opening, and the accommodation space is configured to accommodate the coolant and in communication with an exterior through the upper opening;
an upper cover, detachably disposed above the container body and configured to seal the upper opening;
a fluid inlet, arranged below the container body and in communication with the accommodation space, wherein the coolant is allowed flowing into the accommodation space from a bottom of the container body through the fluid inlet;
a fluid outlet, arranged on a lateral side of the container body; and
a filter element, accommodated within the accommodation space through the upper opening and arranged between the fluid inlet and the fluid outlet, wherein the coolant enters the accommodation space through the fluid inlet, flows through the filter element, and then is discharged through the fluid outlet.

8. The liquid cooling system according to claim 7, further comprising a buffer tank, wherein the fluid inlets of the plurality of cooling filter structures are jointly coupled to the buffer tank, and the buffer tank is configured to collect the coolant contained in the accommodation spaces of the plurality of cooling filter structures through the fluid inlets when the plurality of coolant transmission pipelines stop transporting the coolant.

9. The liquid cooling system according to claim 8, further comprising a mini pump connected to the buffer tank, wherein the mini pump is configured to transport the coolant from the buffer tank to a main pump suction of the reservoir and pumping unit or the system reservoir.

10. The liquid cooling system according to claim 7, wherein the upper cover comprises a cap bump spatially corresponding to the upper opening and accommodated in the container body when the upper cover seals the upper opening.

11. The liquid cooling system according to claim 7, wherein the upper cover comprises a through hole, and the coolant filter structure further comprises an exhaust valve disposed on the upper cover, in communication with the accommodation space of the container body through the through hole, and configured to eliminate a gas in the container body.

12. The liquid cooling system according to claim 7, wherein when the upper cover is detached from the upper opening, the coolant forms a liquid level in the container body that is lower than the upper opening, and the filter element is allowed to pass through the upper opening.

13. The liquid cooling system according to claim 7, wherein the filter element is directly connected to the upper cover to form an integrated structure.

14. The liquid cooling system according to claim 7, wherein each of the plurality of coolant filter structures further comprises a gasket, wherein the gasket is detachably disposed between the container body and the upper cover, and the container body and the upper cover are connected through a sanitary clamp, so that the gasket is sandwiched between the container body and the upper cover.
